(19) United States
(12) Patent Application Publication
(10) Pub. No.: US 2025/0359123 A1
(43) Pub. Date: Nov. 20, 2025

(54) SEMICONDUCTOR STRUCTURE AND FABRICATING METHOD THEREOF

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/894,960

(22) Filed: Sep. 24, 2024

(30) Foreign Application Priority Data
May 14, 2024 (CN) 202410598227.4

(51) Int. Cl. H01L 29/778; H01L 27/088; H01L 29/20; H01L 29/423; H01L 29/66

(52) U.S. Cl. CPC H10D 30/47; H10D 30/015; H10D 62/8503; H10D 64/411; H10D 84/84

(57) ABSTRACT

Disclosed are a semiconductor structure and a fabricating method thereof. The semiconductor structure includes a substrate, a channel layer, a barrier layer and a first P-type semiconductor layer stacked sequentially, the channel layer and the barrier layer form a heterojunction, and the 2DEG at the channel may be depleted by the first P-type semiconductor layer, so as to implement an enhancement mode device; and a sidewall of the first P-type semiconductor layer, a sidewall of the aluminum-containing film layer, and a sidewall of the gate contact layer that are aligned are stacked sequentially on the barrier layer in a gate region, and a material of the aluminum-containing film layer includes at least any one of AlN, AlON or Al₂O₃.

### CROSS-REFERENCE TO RELATED APPLICATIONS

The present disclosure claims priority to Chinese Patent Application No. 202410598227.4, filed on May 14, 2024, all contents of which are incorporated herein in its entirety by reference.

### TECHNICAL FIELD

The present disclosure relates to the field of semiconductor technologies, in particular, to a semiconductor structure and a fabricating method thereof.

### BACKGROUND

Compared with a first-generation semiconductor material and a second-generation semiconductor material, a third-generation semiconductor material, especially a GaN-based material (gallium nitride) has advantages of wide band gap, high breakdown field strength, high electron mobility, strong radiation resistance and the like. The GaN-based High Electron Mobility Transistor (HEMT) device has great development potential in high-frequency and high-power fields such as wireless communication base stations, radars, automobile electronics, and the like.

In general, the GaN-based HEMT device is a depletion mode field effect transistor, for example, a negative turn-on voltage needs to be used in a radio frequency microwave application, which makes a circuit structure become complex and the anti-misoperation protection function of the circuit is also affected, and thereby a safety of the circuit is reduced, and therefore, it is necessary to carry out a research on an enhancement mode GaN-based HEMT device. The P-type gate is adopted in a conventional GaN-based HEMT device to achieve enhancement mode, but there are still many problems such as relatively low breakdown voltage.

### SUMMARY

In view of this, embodiments of the present disclosure provide a semiconductor structure and a fabricating method thereof, to solve the technical problems of relatively low breakdown voltage in the prior art.

According to an aspect of the present disclosure, an embodiment of the present disclosure provides a semiconductor structure, the semiconductor structure includes: a substrate, a channel layer and a barrier layer stacked sequentially, where the channel layer and the barrier layer include a gate region, a source region located at a side of the gate region and a drain region located at another side of the gate region, where the gate region includes: a first P-type semiconductor layer, an aluminum-containing film layer and a gate contact layer stacked sequentially at a side, away from the substrate, of barrier layer, and a sidewall of the first P-type semiconductor, a sidewall of the aluminum-containing film layer and a sidewall of the gate contact layer are aligned, the source region includes: a source contact layer at a side, away from the substrate, of the channel layer, and the drain region includes: a drain contact layer at the side, away from the substrate, of the channel layer.

In an embodiment of the present disclosure, the sidewall of the first P-type semiconductor layer, the sidewall of the aluminum-containing film layer and the sidewall of the gate contact layer are all perpendicular to a plane where the substrate is located.

In an embodiment of the present disclosure, a thickness of the aluminum-containing film layer is 2 nm-10 nm.

In an embodiment of the present disclosure, the aluminum-containing film layer is a single-layer structure of any one of AlN, AlON or Al₂O₃, or a multi-layer structure containing any two or three of AlN, AlON or Al₂O₃.

In an embodiment of the present disclosure, the aluminum-containing film layer is the multi-layer structure, in the aluminum-containing film layer, a film layer with a high oxygen component is located at a side, away from the substrate, of a film layer with a low oxygen component; and/or, the film layer with the high oxygen component forms a sidewall of the film layer with the low oxygen component.

In an embodiment of the present disclosure, the film layer with the high oxygen component is located at the side, away from the substrate, of the film layer with the low oxygen component, and a thickness of the film layer with the high oxygen component is less than a thickness of the film layer with the low oxygen component.

In an embodiment of the present disclosure, the thickness of the film layer with the high oxygen component ranges from 5 nm-40 nm, and the thickness of the film layer with the low oxygen component ranges from 20 nm-100 nm.

In an embodiment of the present disclosure, the source region includes an N-type doped source region, and the N-type doped source region is located between the source contact layer and the channel layer; and the drain region includes an N-type doped drain region, and the N-type doped drain region is located between the drain contact layer and the channel layer.

In an embodiment of the present disclosure, at least one of the N-type doped source region or the N-type doped drain region includes a superlattice structure.

In an embodiment of the present disclosure, in a direction extending from a channel formed between the channel layer and the barrier layer away from the substrate, at least one of a concentration of an N-type doping in the N-type doped source region or a concentration of an N-type doping in the N-type doped drain region decreases gradually.

In an embodiment of the present disclosure, in a direction extending from a channel formed between the channel layer and the barrier layer away from the substrate, at least one of a concentration of an N-type doping in the N-type doped source region or a concentration of an N-type doping in the N-type doped drain region decreases at first and then increases.

In an embodiment of the present disclosure, a doping concentration of the N-type doped source region and a doping concentration of the N-type doped drain region are each greater than 1×10¹⁸/cm³.

In an embodiment of the present disclosure, the semiconductor structure further includes: an insulating protection layer with openings, where the insulating protection layer covers the gate contact layer, the source contact layer, the drain contact layer and the barrier layer, and the gate contact layer, the source contact layer and the drain contact layer are exposed at the openings.

In an embodiment of the present disclosure, the semiconductor structure further includes: a second P-type semiconductor layer located at a side, away from the substrate, of the barrier layer, where the second P-type semiconductor layer is located between the gate region and the drain region.

In an embodiment of the present disclosure, in a direction perpendicular to a plane where the substrate is located, and a thickness of the second P-type semiconductor layer is less than a thickness of the first P-type semiconductor layer.

In an embodiment of the present disclosure, a concentration of a P-type doping in the second P-type semiconductor layer is less than a concentration of a P-type doping of the first P-type semiconductor layer.

According to another aspect of the present disclosure, an embodiment of the present disclosure provides a fabricating method of a semiconductor structure, the fabricating method includes: sequentially epitaxially fabricating a channel layer and a barrier layer on a substrate, where the channel layer and the barrier layer include a gate region, a source region located at a side of the gate region and a drain region located at another side of the gate region; epitaxially fabricating a P-type semiconductor material layer at a side, away from the substrate, of the barrier layer; depositing an aluminum-containing material layer at a side, away from the substrate, of the P-type semiconductor material layer; etching the aluminum-containing material layer and the P-type semiconductor material layer that are located on the source region and the drain region; depositing a metal material layer; etching and removing the metal material layer located between the gate region and the source region and the metal material layer located between the gate region and the drain region to form a gate contact layer located in the gate region, a source contact layer located in the source region and a drain contact layer located in the drain region; and using the gate contact layer, the source contact layer and the drain contact layer as masks, and etching the aluminum-containing material layer and the P-type semiconductor material layer to form a first P-type semiconductor layer and an aluminum-containing film layer located in the gate region, so that a sidewall of the first P-type semiconductor, a sidewall of the aluminum-containing film layer and a sidewall of the gate contact layer are aligned.

In an embodiment of the present disclosure, after the depositing an aluminum-containing material layer at a side, away from the substrate, of the P-type semiconductor material layer, further includes: depositing a sacrificial layer on the aluminum-containing material layer; etching the sacrificial layer, the aluminum-containing material layer, the P-type semiconductor material layer, the barrier layer and at least a part of the channel layer that are located in the source region and the drain region to form a groove located in the source region and the drain region; using the sacrificial layer as a mask and respectively epitaxially fabricating an N-type doped source region and an N-type doped drain region in the groove of the source region and the drain region; etching and removing the sacrificial layer; and re-depositing the metal material layer.

In an embodiment of the present disclosure, the aluminum-containing material layer and the P-type semiconductor material layer are etched, an etching direction is perpendicular to a plane where the substrate is located, so that the sidewall of the first P-type semiconductor layer, the sidewall of the aluminum-containing film layer and the sidewall of the gate contact layer are all perpendicular to the plane where the substrate is located.

In an embodiment of the present disclosure, the fabricating method further includes: depositing an insulating protection layer, where the insulating protection layer covers the gate contact layer, the source contact layer, the drain contact layer and the barrier layer; and etching the insulating protection layer to form openings for exposing the gate contact layer, the source contact layer and the drain contact layer, where the openings are used for metal interconnection in back end of line.

### BRIEF DESCRIPTION OF THE DRAWINGS

FIG. 1 is a schematic structural diagram of a semiconductor structure according to an embodiment of the present disclosure.

FIG. 2 is a schematic structural diagram of a gate region according to an embodiment of the present disclosure.

FIG. 3 is a schematic structural diagram of another gate region according to an embodiment of the present disclosure.

FIG. 4 is a schematic structural diagram of another gate region according to an embodiment of the present disclosure.

FIG. 5 is a schematic structural diagram of another semiconductor structure according to an embodiment of the present disclosure.

FIG. 6 is a schematic structural diagram of another semiconductor structure according to an embodiment of the present disclosure.

FIG. 7 is a schematic structural diagram of another semiconductor structure according to an embodiment of the present disclosure.

FIG. 8 is a schematic structural diagram of another semiconductor structure according to an embodiment of the present disclosure.

FIG. 9 to FIG. 13 are schematic structural diagrams of intermediate structures for fabricating a semiconductor structure according to an embodiment of the present disclosure.

FIG. 14 to FIG. 19 are schematic structural diagrams of intermediate structures for fabricating another semiconductor structure according to an embodiment of the present disclosure.

FIG. 20 is a schematic structural diagram of an intermediate structure for fabricating another semiconductor structure according to an embodiment of the present disclosure.

FIG. 21 is a schematic flowchart of a fabricating method of a semiconductor structure according to an embodiment of the present disclosure.

FIG. 22 is a schematic flowchart of a fabricating method of a semiconductor structure according to an embodiment of the present disclosure.

### DETAILED DESCRIPTION OF THE EMBODIMENTS

Technical solutions in the embodiments of the present disclosure will be clearly described below with reference to the accompanying drawings in the embodiments of the present disclosure. Apparently, the described embodiments are a part of the embodiments of the present disclosure, rather than all the embodiments.

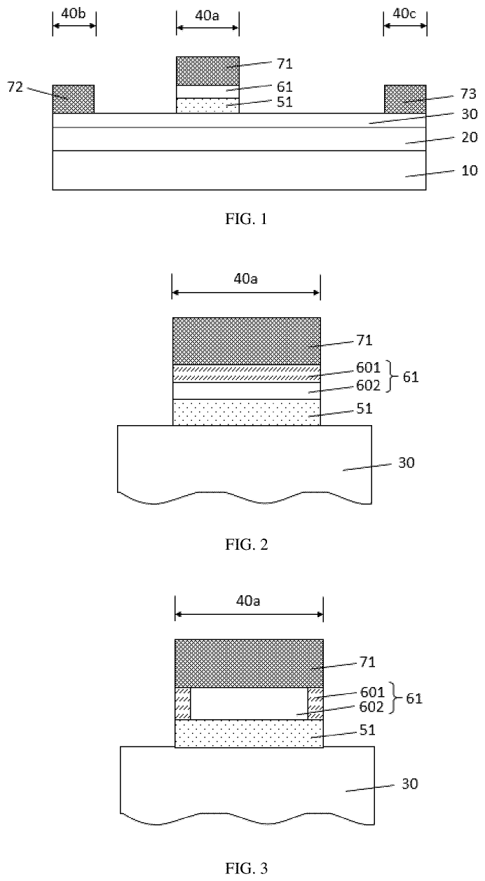

In order to solve the above problems, the present disclosure provides a semiconductor structure and a fabricating method thereof. The following further illustrates the semiconductor structure and the fabricating method thereof mentioned in the present disclosure with reference to FIG. 1 to FIG. 15.

FIG. 1 is a schematic structural diagram of a semiconductor structure according to an embodiment of the present disclosure. As shown in FIG. 1, the semiconductor structure includes: a substrate 10, a channel layer 20 and a barrier layer 30 stacked sequentially, and the channel layer 20 and the barrier layer 30 include a gate region 40a, and a source region 40b located at a side of the gate region 40a and a drain region 40c located at another side of the gate region 40a. The gate region 40a includes a first P-type semiconductor layer 51, an aluminum-containing film layer 61 and a gate contact layer 71 stacked sequentially at a side, away from the substrate 10, of barrier layer 30, and a sidewall of the first P-type semiconductor 51, a sidewall of the aluminum-containing film layer 61 and a sidewall of the gate contact layer 71 are aligned. A material of the aluminum-containing film layer 61 includes at least any one of AlN, AlON or Al₂O₃. The source region 40b includes a source contact layer 72 at a side, away from the substrate 10, of the channel layer 20. The drain region 40c includes a drain contact layer 73 at the side, away from the substrate 10, of the channel layer 20.

Specifically, as shown in FIG. 1, the channel layer 20 and the barrier layer 30 form a heterojunction, and a two-dimensional electron gas (2DEG) at a channel is formed on a surface, close to the barrier layer 30, of the channel layer 20. When no voltage is applied to the semiconductor device, the first P-type semiconductor layer 51 may deplete the 2DEG at the channel, so as to implement an enhancement mode device. In the gate region 40a, the first P-type semiconductor layer 51, the aluminum-containing film layer 61 and the gate contact layer 71 are disposed on the barrier layer 30, and a band gap of the aluminum-containing film layer 61 located in the middle layer is greater than a band gap of the first P-type semiconductor layer 51, so that the Schottky barrier height between the gate contact layer 71 and the first P-type semiconductor layer 51 may be increased, thereby increasing a breakdown voltage. Meanwhile, the sidewall of the first P-type semiconductor layer 51, the sidewall of the aluminum-containing film layer 61 and the sidewall of the gate contact layer 71 are aligned, which may be achieved through a metal self-alignment process of the gate contact layer 71, thereby simplifying the fabrication process. Secondly, the sidewalls of the gate contact layer 71 and the first P-type semiconductor layer 51 are aligned, which may easily lead to leakage. By inserting the aluminum-containing film layer 61 in between the the gate contact layer 71 and the first P-type semiconductor layer 51, the gate leakage current may be reduced.

Specifically, the insulating AlN, AlON or Al₂O₃ is located between the first P-type semiconductor layer 51 and the gate contact layer 71, which may improve the breakdown voltage of the device, and the dense characteristic thereof may reduce electron scattering on a surface of the first P-type semiconductor layer and reduce the gate leakage current.

In an embodiment, as shown in FIG. 1, the sidewall of the first P-type semiconductor layer 51, the sidewall of the aluminum-containing film layer 61 and the sidewall of the gate contact layer 71 are all perpendicular to a plane where the substrate 10 is located. Specifically, a material of the gate contact layer 71 is metal, such as Ni and Au, and the aluminum-containing film layer 61 and the first P-type semiconductor layer 51 are etched by using the gate contact layer 71 as a mask to implement a plane where the sidewall is perpendicular to the substrate.

In an embodiment, a thickness of the aluminum-containing film layer 61 is 2 nm-10 nm. Specifically, the thickness of the aluminum-containing film layer is greater than or equal to 2 nm, and the thickness of the aluminum-containing film layer may be appropriately increased to improve insulation characteristics. The thickness of the aluminum-containing film layer is less than or equal to 10 nm, and the thickness of the aluminum-containing film layer may not be excessively increased to avoid reducing the gate control capability and affecting the performance of the semiconductor device.

In an embodiment, the aluminum-containing film layer is a multi-layer structure containing any two or three of AlN, AlON and Al₂O₃.

Specifically, the aluminum-containing film layer 61 is a two-layer structure, the material of the two-layer structure may include AlN and AlON, AlON and Al₂O₃, or AlN and Al₂O₃. Specifically, the aluminum-containing film layer 61 is a three-layer structure, and the material of the three-layer structure includes AlN, AlON and Al₂O₃.

In an embodiment, in the aluminum-containing film layer 61, a film layer with a high oxygen component is located at a side, away from the substrate, of a film layer with a low oxygen component; and/or the film layer with a high oxygen component forms a sidewall of the film layer with the low oxygen component.

Optionally, FIG. 2 is a schematic structural diagram of a gate region according to an embodiment of the present disclosure. As shown in FIG. 2, in the aluminum-containing film layer 61, the film layer 601 with a high oxygen component is located at the side, away from the substrate 10, of the film layer 602 with a low oxygen component. Specifically, before the gate contact layer 71 is fabricated, an oxidation treatment is performed on the upper surface of the aluminum-containing film layer 61, so that the oxygen component of the upper surface of the aluminum-containing film layer 61 is relatively high, and therefore, the film layer 601 with a high oxygen component is located above the film layer 602 with a low oxygen component, then the gate contact layer 71 is fabricated, and the gate region as shown in FIG. 2 is obtained by the metal self- alignment process. Optionally, in order to prevent the oxidation treatment from affecting under the semiconductor film layer, a thickness of the film layer 601 with the high oxygen component is less than a thickness of the film layer 602 with the low oxygen component. For example, the thickness of the film layer 601 with the high oxygen component ranges from 5 nm-40 nm, and the thickness of the film layer 602 with the low oxygen component ranges from 20 nm-100 nm.

Optionally, FIG. 3 is a schematic structural diagram of another gate region according to an embodiment of the present disclosure. As shown in FIG. 3, in the aluminum-containing film layer 61, the film layer 601 with the high oxygen component forms the sidewall of the film layer 602 with the low oxygen component, that is, the film layer 602 with the low oxygen component is surrounded by the film layer 601 with the high oxygen component. Specifically, after the gate region as shown in FIG. 1 is obtained by the metal self-alignment process, an oxidation treatment is performed on the sidewall of the aluminum-containing film layer 61 to obtain the gate region as shown in FIG. 3 finally. Optionally, in a direction parallel to the plane where the substrate 10 is located, the thickness of the film layer 601, close to the drain region, with the high oxygen component is greater than the thickness of the film layer 601, close to the source region, with the high oxygen component, because the gate region is prone to leakage current at a side close to the drain region, the thickness of the film layer 601, close to the drain region, with the high oxygen component is appropriately increased to improve the reliability of the device.

Specifically, the oxygen component in Al₂O₃ is greater than the oxygen component in AlON, and the oxygen component in AlON is greater than the oxygen component in AlN. Therefore, when the film layer 602 with the low oxygen component is AlN, the film layer 601 with the high oxygen component selects Al₂O₃ or AlON; or when the film layer 602 with the low oxygen component is AlON, the film layer 601 with the high oxygen component selects Al₂O₃. Optionally, when the aluminum-containing film layer 61 is the three-layer structure including AlN, AlON and Al₂O₃, and in a direction from the substrate 10 to the channel layer 20, AlN, AlON and Al₂O₃ are sequentially arranged; or in the plane where the substrate 10 is located, AlN, AlON and Al₂O₃ are sequentially arranged in a direction from the center point of the aluminum-containing film layer 61 to the side.

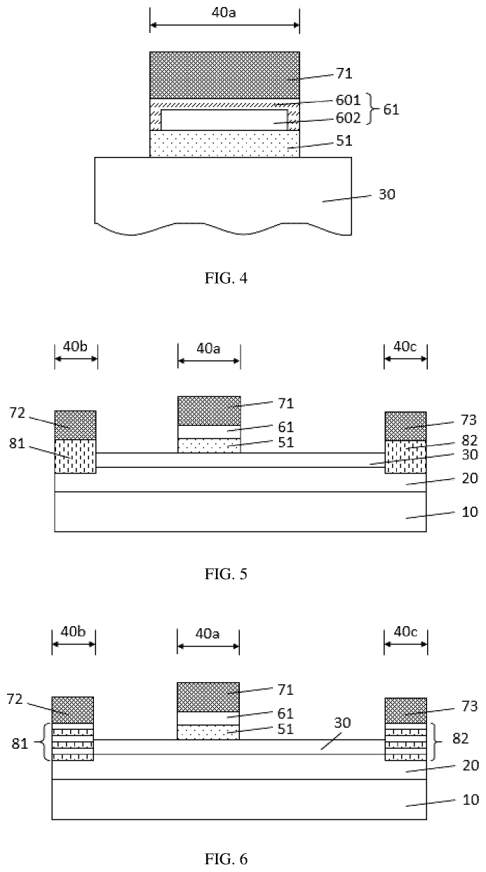

Optionally, FIG. 4 is a schematic structural diagram of another gate region according to an embodiment of the present disclosure. As shown in FIG. 4, in the aluminum-containing film layer 61, the film layer 601 with the high oxygen component is located at a side, away from the substrate, of the film layer 602 with the low oxygen component; and/or the film layer 601 with the high oxygen component forms a sidewall of the film layer 602 with the low oxygen component. Specifically, before the gate contact layer 71 is fabricated, the oxidation treatment is performed on the upper surface of the aluminum-containing film layer 61, so that a part of the film layer 601 with the high oxygen component is located at the top; and then the gate contact layer 71 is fabricated, the gate region as shown in FIG. 2 is obtained by the metal self-alignment process; and the oxidation treatment is performed on the sidewall of the aluminum-containing film layer 61 to obtain the gate region as shown in FIG. 4 finally.

In an embodiment, FIG. 5 is a schematic structural diagram of another semiconductor structure according to an embodiment of the present disclosure. As shown in FIG. 5, the source region 40b includes an N-type doped source region 81, and the N-type doped source region 81 is located between the source contact layer 72 and the channel layer 20; and the drain region 40c includes an N-type doped drain region 82, and the N-type doped drain region 82 is located between the drain contact layer 73 and the channel layer 20. The gate region 40a improves the breakdown resistance, and a resistance of the gate region 40a is relatively large, so in the source region 40b, the N-type doped source region 81 is located between the source contact layer 72 and the channel layer 20, and the N-type doped source region 81 is in ohmic contact with the source contact layer 72, so that the resistance of the ohmic contact between the source contact layer 72 and the channel layer 20 may be reduced. Similarly, the N-type doped drain region 82 in the drain region 40c may reduce the resistance of the ohmic contact between the drain contact layer 73 and the channel layer 20, thereby reducing an integral resistance of the semiconductor structure and improving an electrical performance of the semiconductor structure.

In an embodiment, FIG. 6 is a schematic structural diagram of another semiconductor structure according to an embodiment of the present disclosure. As shown in FIG. 6, at least one of the N-type doped source region 81 or the N-type doped drain region 82 includes a superlattice structure. Specifically, the superlattice structure may further reduce the resistance, and the concentration of the 2DEG at the channel may be improved by a polarization effect, and the mobility of the 2DEG is increased. Optionally, the superlattice structure includes a stacked structure formed by periodically alternating GaN layers and AlGaN layers in a direction perpendicular to the plane where the substrate 10 is located, or the superlattice structure includes a stacked structure formed by periodically alternating GaN layers and InGaN layers in the direction perpendicular to the plane where the substrate 10 is located. Optionally, the N-type doped source region 81 and the N-type doped drain region 82 are an N-type heavily doped, and the doping concentration is greater than 1×10¹⁸/cm³.

In one embodiment, in a direction extending from a channel formed between the channel layer 20 and the barrier layer 30 away from the substrate 10, at least one of a concentration of an N-type doping in the N-type doped source region 81 or a concentration of the N-type doping in the N-type doped drain region 82 decreases gradually. Specifically, the resistance between the channel formed between the channel layer 20 and the barrier layer 30 and the N-type doped source region 81 and the N-type doped drain region 82 affects the on-resistance of the device. Therefore, a concentration of an N-type doping in the channel formed between the channel layer 20 and the barrier layer 30 corresponding to the N-type doped source region 81 and/or the N-type doped drain region 82, the integral on-resistance may be reduced, and the performance of the device may be improved.

Further, in a direction extending from the channel formed between the channel layer 20 and the barrier layer 30 away from the substrate 10, at least one of a concentration of the N-type doping in the N-type doped source region 81 or a concentration of the N-type doping in the N-type doped drain region 82 decreases at first and then increases. Specifically, the resistance between the source contact layer 72 and the N-type doped source region 81 and the resistance between the drain contact layer 73 and the N-type doped drain region 82 are a second major factor affecting the on-resistance of the device, so that the concentration of the N-type doping in the N-type doped source region 81 close to the source contact layer 72 may be increased, and the concentration of the N-type doping in the N-type doped drain region 82 close to the drain contact layer 73 may be increased, thereby reducing the on-resistance of the device and improving the device performance.

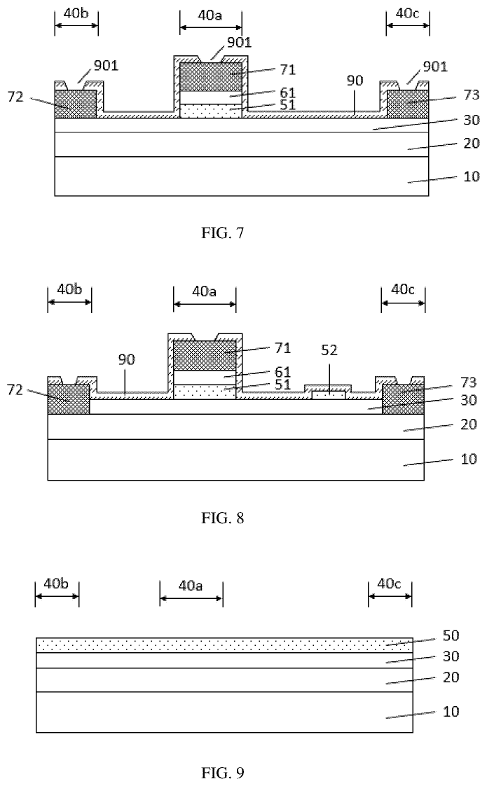

In an embodiment, FIG. 7 is a schematic structural diagram of another semiconductor structure according to an embodiment of the present disclosure. As shown in FIG. 7, the semiconductor structure further includes an insulating protection layer 90 with openings, the insulating protection layer 90 covers the gate contact layer 71, the source contact layer 72, the drain contact layer 73 and the barrier layer 30, and the gate contact layer 71, the source contact layer 72 and the drain contact layer 73 are exposed at the openings 901. Specifically, an upper surface of the semiconductor structure is covered by the insulating protection layer 90 to protect inner structures of the semiconductor structure. The openings 901 are provided with a metal structure to deliver electrical signals for the gate contact layer 71, the source contact layer 72, and the drain contact layer 73 underneath. Optionally, a material of the insulating protection layer 90 is selected from SiO₂ or SiN.

In an embodiment, FIG. 8 is a schematic structural diagram of another semiconductor structure according to an embodiment of the present disclosure. As shown in FIG. 8, the semiconductor structure further includes: a second P-type semiconductor layer 52 located at a side, away from the substrate 10, of the barrier layer 30, and the second P-type semiconductor layer 52 is located between the gate region 40a and the drain region 40c. Specifically, the second P-type semiconductor layer 52 provides a gentle electric field distribution at a side of the drain region 40c, which may reduce current collapse.

Optionally, as shown in FIG. 8, the insulating protection layer 90 covers the second P-type semiconductor layer 52 to protect the second P-type semiconductor layer 52.

Optionally, as shown in FIG. 8, in a direction perpendicular to a plane where the substrate 10 is located, a thickness of the second P-type semiconductor layer 52 is less than a thickness of the first P-type semiconductor layer 51, and the function of the second P-type semiconductor layer 52 may be to reduce the concentration of 2DEG in the lower channel, rather than to implement the normally-off state.

Optionally, a concentration of a P-type doping in the second P-type semiconductor layer 52 is less than a concentration of the P-type doping of the first P-type semiconductor layer 51, and the function of the second P-type semiconductor layer 52 may be to reduce the concentration of the 2DEG in the lower channel, rather than to implement the normally-off state.

Optionally, the second P-type semiconductor layer 52 and the first P-type semiconductor layer 51 are made of the same material, and the second P-type semiconductor layer 52 and the first P-type semiconductor layer 51 may be formed simultaneously, thereby simplifying the fabrication process.

In an embodiment, the present disclosure provides a fabricating method of a semiconductor structure, FIG. 9 to FIG. 13 are schematic diagrams of intermediate structures for fabricating a semiconductor structure according to an embodiment of the present disclosure, and the fabricating method includes the following steps:

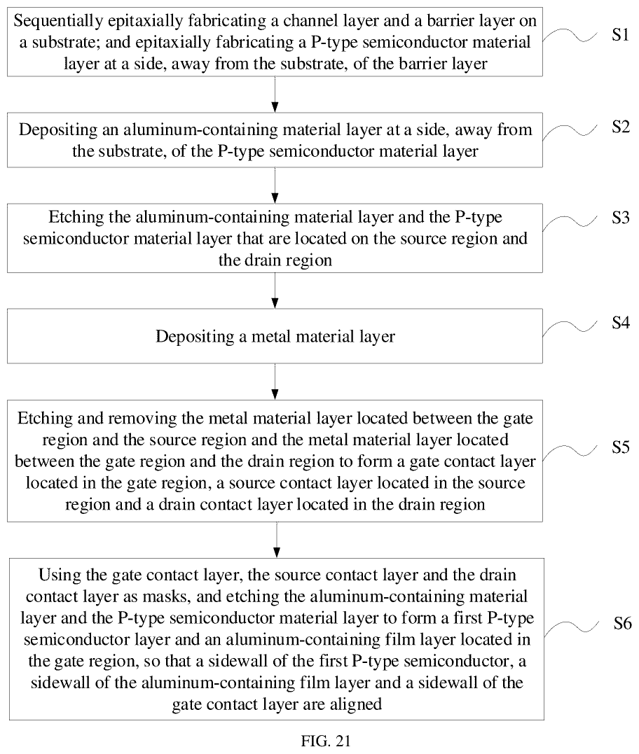

Step S1, as shown in FIG. 9 and FIG. 21, sequentially epitaxially fabricating a channel layer 20 and a barrier layer 30 on a substrate 10, where the channel layer 20 and the barrier layer 30 include a gate region 40a, a source region 40b located at a side of the gate region 40a and a drain region 40c located at another side of the gate region 40a; and epitaxially fabricating a P-type semiconductor material layer 50 at a side, away from the substrate 10, of the barrier layer 30.

Specifically, the substrate 10 may be sapphire, Si, SiC, diamond, or GaN.

Specifically, the channel layer 20 and the barrier layer 30 form a heterojunction, and a channel of (2DEG) is formed on a surface, close to the barrier layer 30, of the channel layer 20. When no voltage is applied to the semiconductor device, the first P-type semiconductor layer 51 may deplete the 2DEG at the channel, so as to implement an enhancement mode device. Optionally, a material of the channel layer 20 and a material of the barrier layer 30 may be a GaN-based semiconductor material, a material of the channel layer 20 is GaN, and a material of the barrier layer 30 is AlGaN. The epitaxial process of the channel layer 20 and the barrier layer 30 may be made by an Atomic Layer Deposition (ALD), or a Chemical Vapor Deposition (CVD), or a molecular Beam Epitaxy (MBE), or a Plasma Enhanced Chemical Vapor Deposition (PECVD), or a Low Pressure Chemical Vapor Deposition (LPCVD), or a Physical Vapor Deposition (PVD), or a Metal Organic Source Molecular Beam Epitaxy (MOMBE), a Metal-Organic Chemical Vapor Deposition (MOCVD), or a combination thereof.

Specifically, the P-type semiconductor material layer 50 has already undergone a P-type activation treatment.

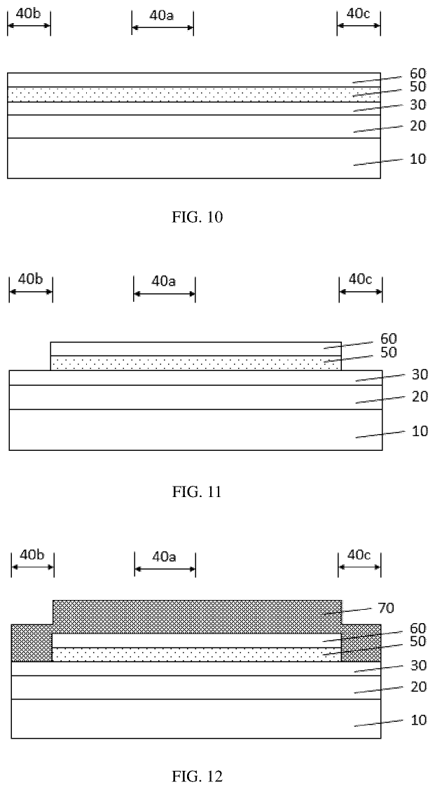

Step S2, as shown in FIG. 10 and FIG. 21, depositing an aluminum-containing material layer 60 at a side, away from the substrate 10, of the P-type semiconductor material layer 50. Specifically, a material of the aluminum-containing material layer 60 includes at least any one of AlN, AlON and Al₂O₃.

Step S3, as shown in FIG. 11 and FIG. 21, etching the aluminum-containing material layer 60 and the P-type semiconductor material layer 50 that are located on the source region 40b and the drain region 40c.

Step S4, as shown in FIG. 12 and FIG. 21, depositing a metal material layer 70. Specifically, the material of the metal material layer 70 includes Ni and Au.

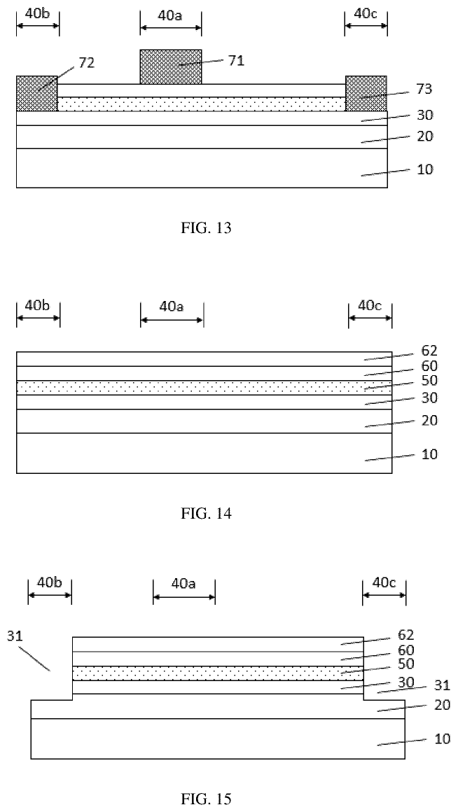

Step S5, as shown in FIG. 13 and FIG. 21, etching and removing the metal material layer 70 located between the gate region 40a and the source region 40b and the metal material layer 70 located between the gate region 40a and the drain region 40c to form a gate contact layer 71 located in the gate region 40a, a source contact layer 72 located in the source region 40b and a drain contact layer 73 located in the drain region 40c.

Step S6, as shown in FIG. 1 and FIG. 21, using the gate contact layer 71, the source contact layer 72 and the drain contact layer 73 as masks, and etching the aluminum-containing material layer 60 and the P-type semiconductor material layer 50 to form a first P-type semiconductor layer 51 and an aluminum-containing film layer 61 located in the gate region 40a, so that a sidewall of the first P-type semiconductor 51, and a sidewall of the aluminum-containing film layer 61 and a sidewall of the gate contact layer 71 are aligned. Specifically, the sidewall of the first P-type semiconductor layer 51, the sidewall of the aluminum-containing film layer 61 and the sidewall of the gate contact layer 71 that are aligned may be simply fabricated by the metal self-alignment process, so as to reduce the gate leakage current of the semiconductor device. The band gap of the aluminum-containing film layer 61 is greater than the band gap of the first P-type semiconductor layer 51, so that the Schottky barrier height between the gate contact layer 71 and the first P-type semiconductor layer 51 may be increased, thereby increasing the breakdown voltage.

In an embodiment, when the aluminum-containing material layer 60 and the P-type semiconductor material layer 50 are etched, an etching direction is perpendicular to the plane where the substrate 10 is located, and the sidewall of the first P-type semiconductor layer 51, the sidewall of the aluminum-containing film layer 61 and the sidewall of the gate contact layer 71 are all perpendicular to the plane where the substrate 10 is located. Specifically, an etching angle is controlled, so that the sidewalls of the above three are perpendicular to the plane where the substrate is located.

In an embodiment, FIG. 14 to FIG. 19 are schematic diagrams of another intermediate structures for fabricating a semiconductor structure according to an embodiment of the present disclosure. After depositing the aluminum-containing material layer 60 at a side, away from the substrate 10, of the P-type semiconductor material layer 50, the fabricating method further includes:

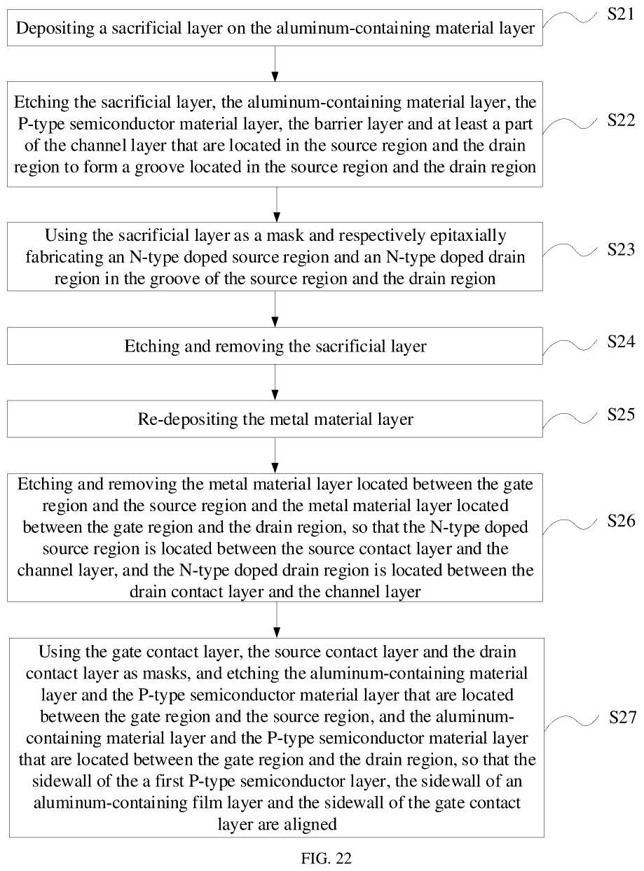

Step S21, as shown in FIG. 14 and FIG. 22, depositing a sacrificial layer 62 on the aluminum-containing material layer 60. Optionally, a material of the sacrificial layer 62 is SiO₂.

Step S22, as shown in FIG. 15 and FIG. 22, etching the sacrificial layer 62, the aluminum-containing material layer 60, the P-type semiconductor material layer 50, the barrier layer 30 and at least a part of the channel layer 20 that are located in the source region 40b and the drain region 40c to form a groove 31 located in the source region 40b and the drain region 40c. Specifically, the etched sacrificial layer 62 is used as a mask, and the groove 31 is formed by etching.

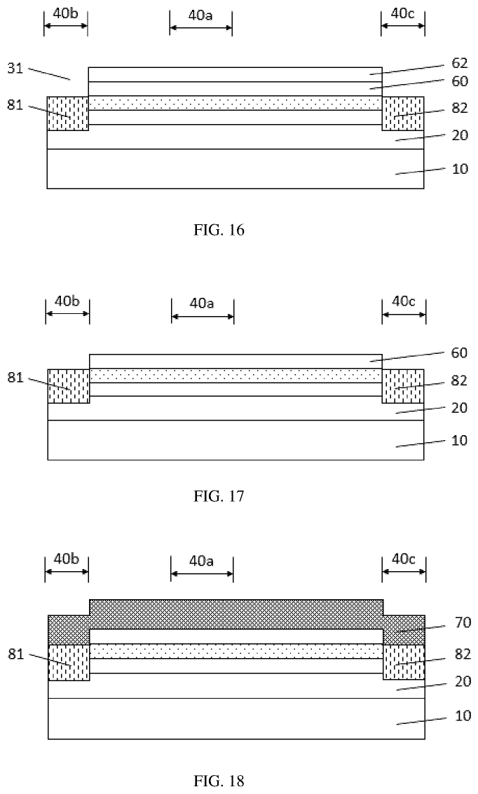

Step S23, as shown in FIG. 16 and FIG. 22, using the sacrificial layer 62 as a mask and respectively epitaxially fabricating an N-type doped source region 81 and an N-type doped drain region 82 in the groove of the source region 40b and the drain region 40c. It should be noted that, in the Step S23, the region covered by the sacrificial layer 62 may not epitaxially form a semiconductor film layer, and the N-type doped region may be only formed in the groove 31. Optionally, the GaN-based material is fabricated by a second epitaxy in the groove 31 and then the N-type doped source region 81 and the N-type doped drain region 82 are obtained by an N-type doping treatment. Optionally, the GaN-based material is fabricated in the groove 31 by the second epitaxy, while an N-type in-situ doping is performed to form the N-type doped source region 81 and the N-type doped drain region 82.

Optionally, as shown in FIG. 16, the N-type doped source region 81 and the N-type doped drain region 82 extend to be flush with the surface of the P-type semiconductor material layer 50.

Step S24, as shown in FIG. 17 and FIG. 22, etching and removing the sacrificial layer 62.

Step S25, as shown in FIG. 18 and FIG. 22, re-depositing the metal material layer 70. Specifically, a material of the metal material layer 70 includes Ni and Au.

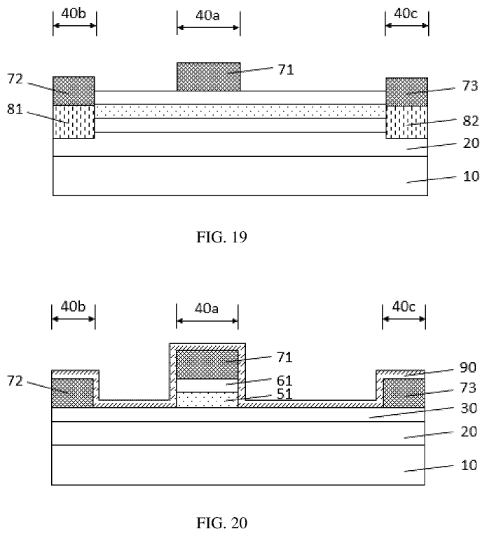

Step S26, as shown in FIG. 19 and FIG. 22, similar to the Step S5, etching and removing the metal material layer 70 located between the gate region 40a and the source region 40b and the metal material layer 70 located between the gate region 40a and the drain region 40c, so that the N-type doped source region 81 is located between the source contact layer 72 and the channel layer 20, and the N-type doped drain region 82 is located between the drain contact layer 73 and the channel layer 20.

Step S27, as shown in FIG. 5 and FIG. 22, similar to the Step S6, using the gate contact layer 71, the source contact layer 72 and the drain contact layer 73 as masks, and etching the aluminum-containing material layer 60 and the P-type semiconductor material layer 50 that are located between the gate region 40a and the source region 40b, and the aluminum-containing material layer 60 and the P-type semiconductor material layer 50 that are located between the gate region 40a and the drain region 40c, so that the sidewall of the a first P-type semiconductor layer 51, the sidewall of an aluminum-containing film layer 61 and the sidewall of the gate contact layer 71 are aligned. Because the gate region 40a improves the breakdown resistance, and a resistance of the gate region 40a is large. Specifically, the N-type doped source region 81 is in ohmic contact with the source contact layer 72, so that the resistance of the ohmic contact between the source contact layer 72 and the channel layer 20 may be reduced, and the resistance of the ohmic contact between the drain contact layer 73 and the channel layer 20 may be reduced due to the N-type doped drain region 82, thereby reducing the integral resistance of the semiconductor structure, and improving the electrical performance of the semiconductor structure.

In an embodiment, FIG. 20 is a schematic diagram of another intermediate structure for fabricating a semiconductor structure according to an embodiment of the present disclosure. As shown in FIG. 20, the fabricating method further includes: depositing an insulating protection layer 90, and the insulating protection layer 90 covers the gate contact layer 71, the source contact layer 72, the drain contact layer 73 and the barrier layer 30. As shown in FIG. 8, etching the insulating protection layer 90 to form openings 901 for exposing the gate contact layer 71, the source contact layer 72 and the drain contact layer 73, and the openings 901 are used for metal interconnection in back end of line.

The present disclosure provides a semiconductor structure and a fabricating method thereof, the semiconductor structure includes a substrate, a channel layer, a barrier layer and a first P-type semiconductor layer stacked sequentially, the channel layer and the barrier layer form a heterojunction, and the 2DEG at the channel may be depleted by the first P-type semiconductor layer, so as to implement an enhancement mode device. The sidewall of the first P-type semiconductor layer, the sidewall of the aluminum-containing film layer, and the sidewall of the gate contact layer which are aligned are stacked sequentially on the barrier layer of the gate region, so as to reduce the gate leakage current, and the Schottky barrier height between the gate contact layer and the first P-type semiconductor layer may be increased, thereby increasing the breakdown voltage, while the alignment of the sidewalls is achieved by the metal self-alignment process that is simpler by the process.

It should be understood that the terms “include” and variations thereof used in the present disclosure are open ended, that is, “including but not limited to”. The term “an embodiment” means “at least one embodiment”. In this specification, specific features, structures, materials, or characteristics described may be combined in any suitable manner in any one or more embodiments or examples. In addition, in the case of no contradiction, a person skilled in the art may combine and integrate different embodiments or examples described in this specification, as well as features of different embodiments or examples.

What is claimed is:

1. A semiconductor structure, comprising a substrate, a channel layer and a barrier layer stacked sequentially, wherein
the channel layer and the barrier layer comprise a gate region, a source region located at a side of the gate region and a drain region located at another side of the gate region;
the gate region comprises: a first P-type semiconductor layer, an aluminum-containing film layer and a gate contact layer stacked sequentially at a side, away from the substrate, of barrier layer, and a sidewall of the first P-type semiconductor, a sidewall of the aluminum-containing film layer and a sidewall of the gate contact layer are aligned;
the source region comprises: a source contact layer at a side, away from the substrate, of the channel layer; and
the drain region comprises: a drain contact layer at the side, away from the substrate, of the channel layer.

2. The semiconductor structure according to claim 1, wherein the sidewall of the first P-type semiconductor layer, the sidewall of the aluminum-containing film layer and the sidewall of the gate contact layer are all perpendicular to a plane where the substrate is located.

3. The semiconductor structure according to claim 1, wherein a thickness of the aluminum-containing film layer is 2 nm-10 nm.

4. The semiconductor structure according to claim 1, wherein the aluminum-containing film layer is a single-layer structure of any one of AlN, AlON or Al₂O₃, or a multi-layer structure containing any two or three of AlN, AlON or Al₂O₃.

5. The semiconductor structure according to claim 4, wherein the aluminum-containing film layer is the multi-layer structure, in the aluminum-containing film layer, a film layer with a high oxygen component is located at a side, away from the substrate, of a film layer with a low oxygen component; and/or,
the film layer with the high oxygen component forms a sidewall of the film layer with the low oxygen component.

6. The semiconductor structure according to claim 5, wherein the film layer with the high oxygen component is located at the side, away from the substrate, of the film layer with the low oxygen component, and a thickness of the film layer with the high oxygen component is less than a thickness of the film layer with the low oxygen component.

7. The semiconductor structure according to claim 6, wherein the thickness of the film layer with the high oxygen component ranges from 5 nm-40 nm, and the thickness of the film layer with the low oxygen component ranges from 20 nm-100 nm.

8. The semiconductor structure according to claim 1, wherein the source region comprises an N-type doped source region, and the N-type doped source region is located between the source contact layer and the channel layer; and
the drain region comprises an N-type doped drain region, and the N-type doped drain region is located between the drain contact layer and the channel layer.

9. The semiconductor structure according to claim 8, wherein at least one of the N-type doped source region or the N-type doped drain region comprises a superlattice structure.

10. The semiconductor structure according to claim 8, wherein in a direction extending from a channel formed between the channel layer and the barrier layer away from the substrate, at least one of a concentration of an N-type doping in the N-type doped source region or a concentration of an N-type doping in the N-type doped drain region decreases gradually.

11. The semiconductor structure according to claim 8, wherein in a direction extending from a channel formed between the channel layer and the barrier layer away from the substrate, at least one of a concentration of an N-type doping in the N-type doped source region or a concentration of an N-type doping in the N-type doped drain region decreases at first and then increases.

12. The semiconductor structure according to claim 8, wherein a doping concentration of the N-type doped source region and a doping concentration of the N-type doped drain region are each greater than 1×10¹⁸/cm³.

13. The semiconductor structure according to claim 1, further comprising: an insulating protection layer with openings, wherein the insulating protection layer covers the gate contact layer, the source contact layer, the drain contact layer and the barrier layer, and the gate contact layer, the source contact layer and the drain contact layer are exposed at the openings.

14. The semiconductor structure according to claim 1, further comprising: a second P-type semiconductor layer located at a side, away from the substrate, of the barrier layer, wherein the second P-type semiconductor layer is located between the gate region and the drain region.

15. The semiconductor structure according to claim 14, wherein in a direction perpendicular to a plane where the substrate is located, and a thickness of the second P-type semiconductor layer is less than a thickness of the first P-type semiconductor layer.

16. The semiconductor structure according to claim 14, wherein a concentration of a P-type doping in the second P-type semiconductor layer is less than a concentration of a P-type doping of the first P-type semiconductor layer.

17. A fabricating method of a semiconductor structure, comprising:
sequentially epitaxially fabricating a channel layer and a barrier layer on a substrate, wherein the channel layer and the barrier layer comprise a gate region, a source region located at a side of the gate region and a drain region located at another side of the gate region;
epitaxially fabricating a P-type semiconductor material layer at a side, away from the substrate, of the barrier layer;
depositing an aluminum-containing material layer at a side, away from the substrate, of the P-type semiconductor material layer;
etching the aluminum-containing material layer and the P-type semiconductor material layer that are located on the source region and the drain region;
depositing a metal material layer;
etching and removing the metal material layer located between the gate region and the source region and the metal material layer located between the gate region and the drain region to form a gate contact layer located in the gate region, a source contact layer located in the source region and a drain contact layer located in the drain region; and
using the gate contact layer, the source contact layer and the drain contact layer as masks, and etching the aluminum-containing material layer and the P-type semiconductor material layer to form a first P-type semiconductor layer and an aluminum-containing film layer located in the gate region, so that a sidewall of the first P-type semiconductor, a sidewall of the aluminum-containing film layer and a sidewall of the gate contact layer are aligned.

18. The fabricating method according to claim 17, wherein after the depositing an aluminum-containing material layer at a side, away from the substrate, of the P-type semiconductor material layer, the fabricating method further comprises:
depositing a sacrificial layer on the aluminum-containing material layer;
etching the sacrificial layer, the aluminum-containing material layer, the P-type semiconductor material layer, the barrier layer and at least a part of the channel layer that are located in the source region and the drain region to form a groove located in the source region and the drain region;
using the sacrificial layer as a mask and respectively epitaxially fabricating an N-type doped source region and an N-type doped drain region in the groove of the source region and the drain region;
etching and removing the sacrificial layer; and
re-depositing the metal material layer.

19. The fabricating method according to claim 17, wherein the aluminum-containing material layer and the P-type semiconductor material layer are etched, an etching direction is perpendicular to a plane where the substrate is located, so that the sidewall of the first P-type semiconductor layer, the sidewall of the aluminum-containing film layer and the sidewall of the gate contact layer are all perpendicular to the plane where the substrate is located.

20. The fabricating method according to claim 17, further comprising:
depositing an insulating protection layer, wherein the insulating protection layer covers the gate contact layer, the source contact layer, the drain contact layer and the barrier layer; and
etching the insulating protection layer to form openings for exposing the gate contact layer, the source contact layer and the drain contact layer, wherein the openings are used for metal interconnection in back end of line.
